(19) United States
(12) Patent Application Publication
(10) Pub. No.: US 2013/0286584 A1
(43) Pub. Date: Oct. 31, 2013

(54) COOLING SYSTEM FOR ELECTRONIC DEVICE AND ELECTRONIC DEVICE HAVING SAME

(71) Applicant: TAI-WEI LIN, Tu-Cheng (TW)

(72) Inventor: TAI-WEI LIN, Tu-Cheng (TW)

(73) Assignee: HON HAI PRECISION INDUSTRY CO., LTD., Tu-Cheng (TW)

(21) Appl. No.: 13/495,695

(22) Filed: Jun. 13, 2012

(30) Foreign Application Priority Data
Apr. 26, 2012 (TW) 101115011

(51) Int. Cl. F28F 27/00; F28D 15/00; H05K 7/20

(52) U.S. Cl. 361/695; 165/96; 165/104.34

(57) ABSTRACT

An electronic device includes a chassis, a circuit board, at least one electronic component, an air conducting cover and a shutter. The circuit board defines at least one inserting slot. The electronic component is detachably attached to the electronic component. The air conducting cover defines an air channel. The air conducting cover is attached to the circuit board. The shutter is retractably fixed to the air conducting cover. When the electronic component is attached to the inserting slot, the shutter is retracted, allowing an air flow drawn by the fan assembly to pass by and cool the electronic component; when the electronic component is not attached to the inserting slot, the shutter is extended to shield the area in the air channel corresponding to the inserting slot, preventing the air flow drawn by the fan assembly from passing through the area.

### BACKGROUND

1. Technical Field

The disclosure generally relates to cooling systems for electronic devices.

2. Description of Related Art

Many electronic components in an electronic device generate heat when operating. In designing an electronic device, cooling systems are used to dissipate heat generated by the electronic components to prevent the electronic components from overheating.

Many cooling systems include an air conducting cover defining an airflow channel, a number of fans and electronic components mounted in the airflow channel. The fans are configured to draw air into the airflow channels and force air to pass the electronic components which are cooled accordingly. However, if an electronic component is not mounted in the predefined area of the airflow channel, the airflow generated by the fans will pass the corresponding empty area which causes bypass airflow. As a result, the effectiveness cooling function of the cooling system is reduced.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary cooling system and electronic device having the cooling system. Moreover, in the drawings, like reference numerals designate corresponding parts throughout the several views. Wherever possible, the same reference numbers are used throughout the drawings to refer to the same or like elements of an embodiment.

FIG. 1 is an exploded view of an embodiment of a cooling system, and an electronic device.

FIG. 2 is an exploded and enlarged view of a shutter of the cooling system in FIG. 1.

FIG. 3 is an assembled view of the electronic device of FIG. 1.

FIG. 4 is a cutaway and enlarged view of the electronic device of FIG. 3.

### DETAILED DESCRIPTION

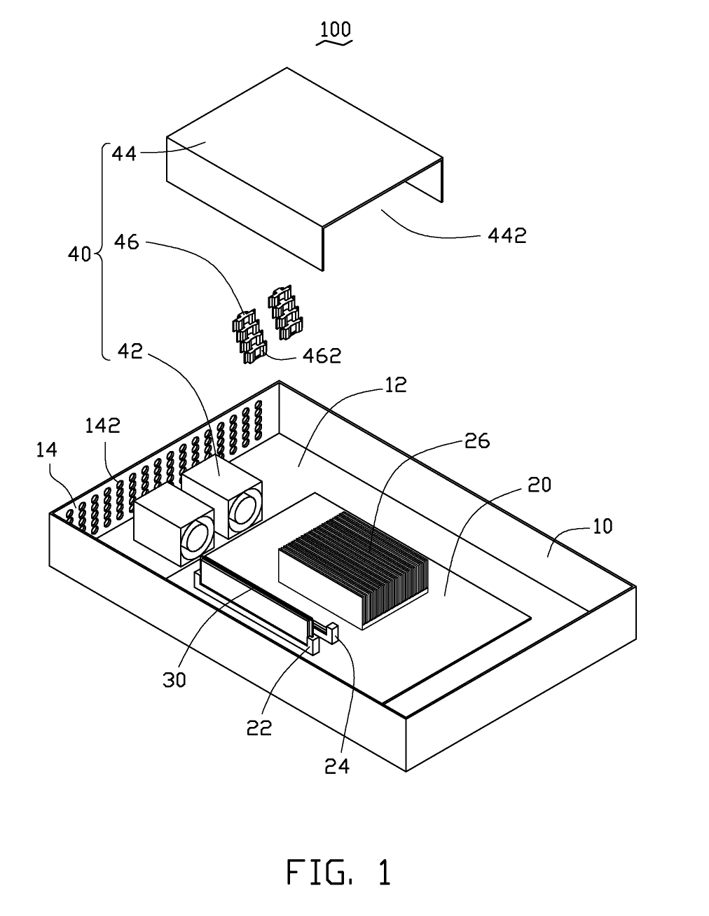

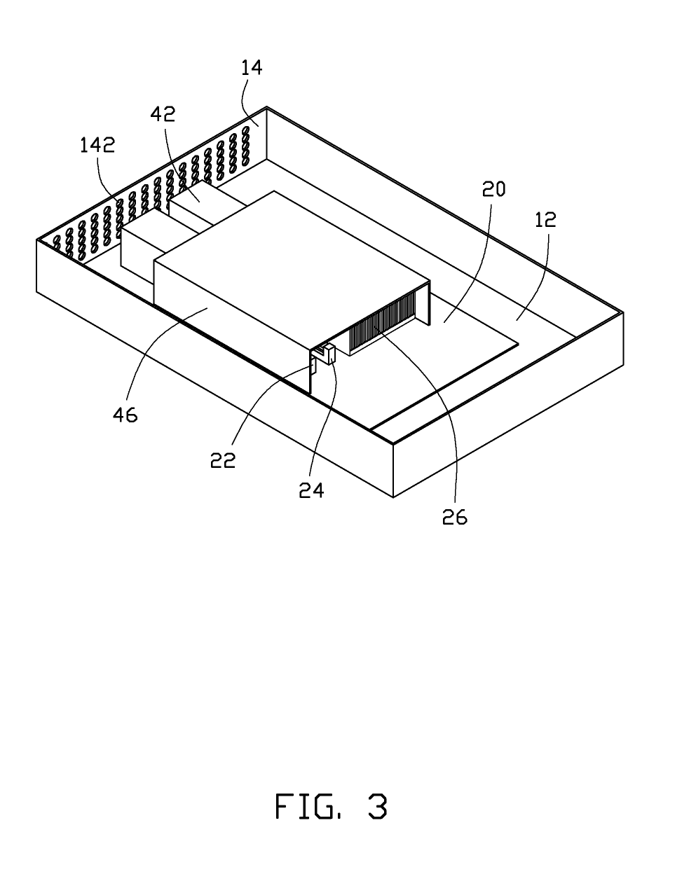

Referring to FIG. 1 and FIG. 3, an electronic device 100, such as a server, includes a chassis 10, a circuit board 20, at least one electronic component 30 and a cooling system 40. The cooling system 40 and the electronic components 30 are both mounted to the chassis 10.

The chassis 10 includes a main board 12 and a plurality of side boards 14 completely surrounds main board 12. One of side boards 14 protrudes from one end of the main board 12 The one of side board 14 defines a plurality of air inlets 142, conducting surrounding air flowing into the chassis 10.

The circuit board 20 is attached to the main board 12. The circuit board 20 includes a first inserting slot 22, a second inserting slot 24 and a heat sink 26. The first inserting slot 22, the second inserting slot 24 and the heat sink 26 are spacedly located on the circuit board 20 side-by-side. The first inserting slot 22 and the second inserting slot 24 may both be expansion slots, such as expansion slots for random access memories. The heat sink 26 may be made of stainless steel. The heat sink 26 cools the circuit board 20 by dissipating heat generated by the circuit board 20 into surrounding air.

The at least one electronic component 30 may be random access memory. The number of the at least one electronic component 30 is accorded to actual need, such as one or two. In this exemplary embodiment, the number of the at least one electronic component 30 is one.

The cooling system 40 includes a fan assembly 42, an air conducting cover 44 and two shutters 46.

The fan assembly 42 draws air flow into the air conducting cover 44, to cool the circuit board 20, the heat sink 26 and the electronic component 30. In this exemplary embodiment, the fan assembly 42 is attached to the main board 12, and located between The one of side board 14 and the circuit board 20.

The air conducting cover 44 is attached to the circuit board 20, to cover the electronic component 30 and the heat sink 26, thereby conducting the air flow drawn by the fan assembly 42 to cool the electronic component 30 and the heat sink 26. In this exemplary embodiment, the air conducting cover 44 is U-shaped and defines an air channel 442 which conducts the air flow passing through the air conducting cover 44.

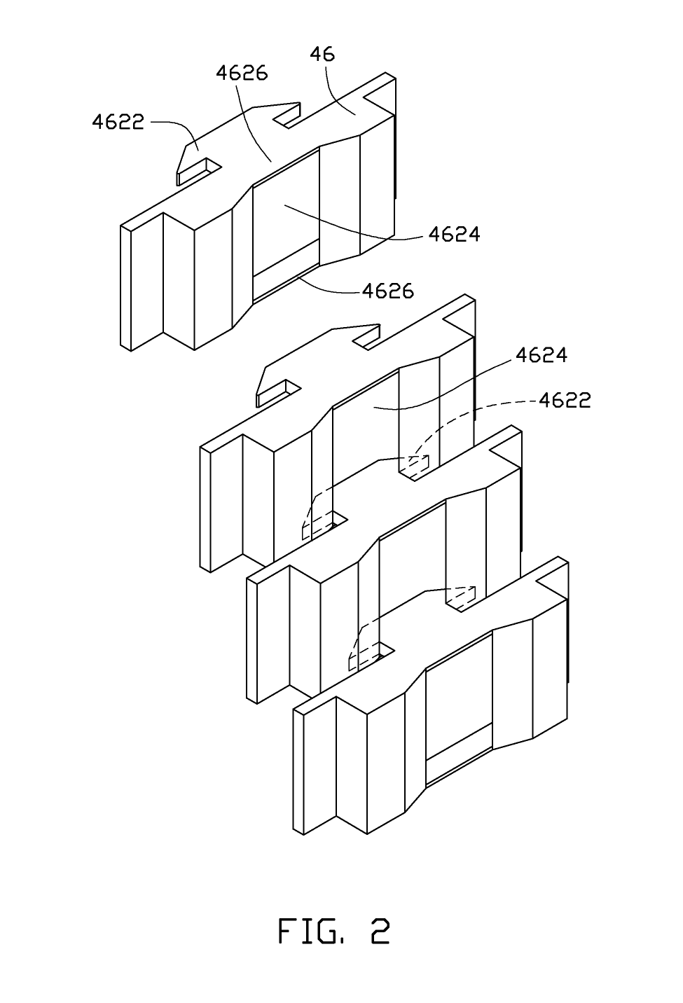

Referring to FIG. 2, the shutters 46 are attached to the air conducting cover 44, to adjust a size of the air channel 442. Each shutter 46 includes a plurality of blinds 462 connecting one to another in series, and adjacent blinds 462 can slide relative to each other so the shutters 46 are retractable. In detail, each blind 462 has a sliding block 4622 and defines a sliding groove 4624, in which the sliding block 4622 of an adjacent blind 462 is slidably attached so the adjacent blinds 462 can slide relative to each other. In this exemplary embodiment, a first surface of each blind 462 has a sliding block 4622, a second surface of each blind 462 opposite the first surface defines a sliding groove 4624.

Furthermore, to prevent the sliding blocks 4622 from sliding out of the corresponding sliding grooves 4624, each blind 462 has two limiting blocks 4626 protruding from opposite ends of the sliding groove 4624.

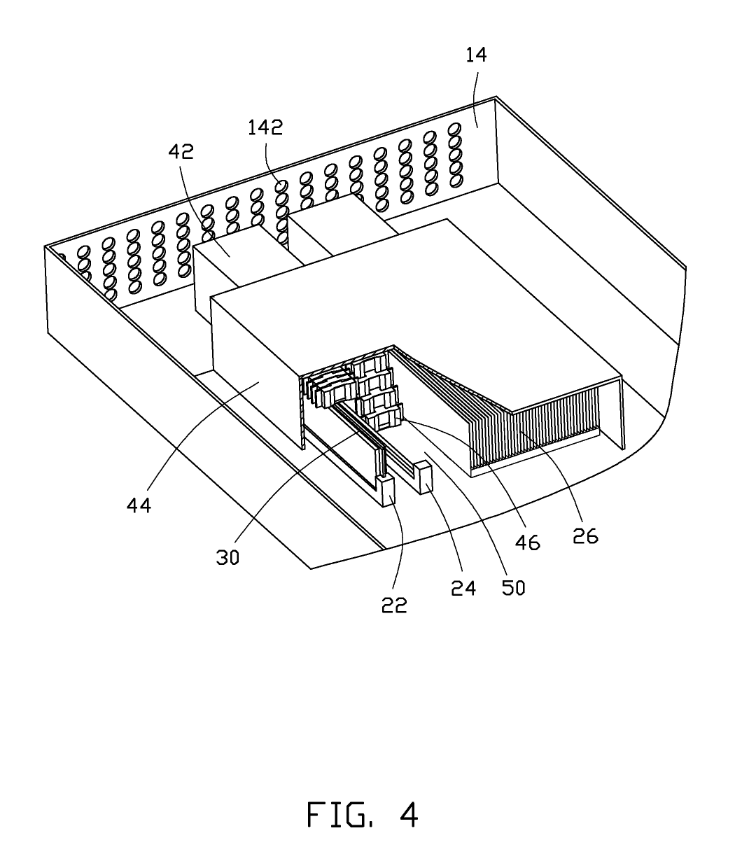

Referring to FIGS. 3 and 4, in assembly, the electronic component 30 is attached to the first inserting slot 22. The fan assembly 42 is attached to the main board 12. One end of each shutter 46 is fixed to the air conducting cover 44. The air conducting cover 44 is attached to the circuit board 20. At this time, one of the shutters 46 is located above the first inserting slot 22, the other is located above the second inserting slot 24.

One advantage of above cooling system 40 is as below: because the electronic component 30 is inserted into the first inserting slot 22, when the shutter 46 associated with the first inserting slot 22 is retracted, the air flow is drawn by the fan assembly 42 to pass by and cool the electronic component 30. Because there is no electronic component 30 inserted into the second inserting slot 24, the shutter 46 located above the second inserting slot 24 is extended to shield the area in the air channel 442 corresponding to the second inserting slot 24, i.e., a gap 50 (FIG. 4) formed between the electronic component 30 and the heat sink 26, preventing the air flow drawn by the fan assembly 42 from passing through the area, to improve the cooling function of the cooling system 40.

It is to be understood, however, that even through numerous characteristics and advantages of the disclosure have been set forth in the foregoing description, together with details of the system and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A cooling system, comprising:
an air conducting cover defining an air channel, the air channel conducting air passing through the air conducting cover; and
a shutter, retractably fixed to the air conducting cover, and located in the air channel, for adjusting a size of the air channel.

2. The cooling system as claimed in claim 1, wherein the shutter includes a plurality of blinds connecting one after another, and adjacent blinds can slide relative to each other making the shutters retractable.

3. The cooling system as claimed in claim 2, wherein each blind has a sliding block and defines a sliding groove, in which the sliding block of an adjacent blind is slidably attached so adjacent blinds can slide relative to each other.

4. The cooling system as claimed in claim 2, wherein each blind has two limiting blocks protruding from opposite ends of the sliding groove, to prevent the sliding blocks from sliding out of the sliding grooves.

5. The cooling system as claimed in claim 1, wherein the cooling system further comprises a fan assembly drawing air flow into the air channel.

6. An electronic device, comprising:
a chassis;
a circuit board attached to the chassis, the circuit board defining at least one inserting slot;
at least one electronic component detachably attached to the at least one electronic component;
an air conducting cover defining an air channel, the air channel conducting air passing through the air conducting cover, the air conducting cover attached to the circuit board so the at least one electronic component is located in the air channel; and
a shutter, retractably fixed to the air conducting cover, and located in the air channel, for adjusting a size of the air channel;
wherein when the at least one electronic component is attached to the at least one inserting slot, the shutter is retracted, allowing an air flow drawn by the fan assembly to pass by and cool the at least one electronic component; when the at least one electronic component is not attached to the at least one inserting slot, the shutter is extended to shield area in the air channel corresponding to the at least one inserting slot, preventing the air flow drawn by the fan assembly from passing through the area.

7. The electronic device as claimed in claim 6, wherein the shutter includes a plurality of blinds connecting one after another, and adjacent blinds can slide relative to each other making the shutters retractable.

8. The electronic device as claimed in claim 7, wherein each blind has a sliding block and defines a sliding groove, in which the sliding block of an adjacent blind is slidably attached so adjacent blinds can slide relative to each other.

9. The electronic device as claimed in claim 7, wherein each blind has two limiting blocks protruding from opposite ends of the sliding groove, to prevent the sliding blocks from sliding out of the sliding grooves.

10. The electronic device as claimed in claim 6, wherein the cooling system further comprises a fan assembly drawing air flow into the air channel.
